(19) United States
(12) Patent Application Publication
(10) Pub. No.: US 2009/0167159 A1
(43) Pub. Date: Jul. 2, 2009

(54) ORGANIC LIGHT EMITTING DEVICE

(75) Inventors: Won-Jun SONG, Suwon-si (KR); Yeun-Joo Sung, Suwon-si (KR); Mu-Hyun Kim, Suwon-si (KR)

Correspondence Address: STEIN MCEWEN, LLP, 1400 EYE STREET, NW, SUITE 300, WASHINGTON, DC, 20005, US

(73) Assignee: Samsung SDI Co., Ltd., Suwon-si (KR)

(21) Appl. No.: 12/133,744

(22) Filed: Jun. 5, 2008

(30) Foreign Application Priority Data
Dec. 28, 2007 (KR) 2007-140555

(51) Int. Cl. H01J 1/63

(52) U.S. Cl. 313/504

(57) ABSTRACT

An organic light emitting device includes a first electrode; a second electrode; an emissive layer disposed between the first electrode and the second electrode; a first hole injection layer disposed between the first electrode and the emissive layer; and a first electron transport layer disposed between the emissive layer and the second electrode. The hole injection layer includes a hole injecting material and a first compound made up of an element selected from the group consisting of Mo, Li, Na, K, Rb, Cs, Be, Mg, Ca, Sr, Ba, and B and an element selected from the group consisting of O, F, S, Cl, Se, Br, and I. The electron transport layer comprises an electron transporting material and a second compound, which is Li₂O, MoO₃, BaO, or B₂O₃.

### CROSS-REFERENCE TO RELATED APPLICATION

This application claims the benefit of Korean Application No. 2007-140555, filed Dec. 28, 2007, in the Korean Intellectual Property Office, the disclosure of which is incorporated herein by reference.

### BACKGROUND OF THE INVENTION

1. Field of the Invention

Aspects of the present invention relate to an organic light emitting device, and more particularly, to an organic light emitting device with improved driving voltage, light emitting efficiency, lifetime, and the like by using a novel hole injecting material and a novel electron transporting material. In addition, aspects of the present invention may contribute to development of a high image quality organic light emitting device, and provide an organic light emitting device with reduced power consumption and improved lifetime.

2. Description of the Related Art

Organic light emitting devices are devices in which, when a current is supplied to an organic layer interposed between two electrodes as shown in FIG. 1, electrons and holes combine in the organic layer to emit light. Such organic light emitting devices can be formed to be light-weight and thin information display devices having a high image quality, quick response time, and wide viewing angles. These features have led to the rapid development of organic light emitting display device technology. Currently, organic light emitting devices are widely applied in mobile phones and other information display devices.

Due to such rapid development of organic light emitting devices, competition with other information display devices such as TFT-LCDs is inevitable in terms of academic and industrial technology. In addition, conventional organic light emitting devices are limited in terms of the amount of efficiency and lifetime improvements and power consumption reduction that is possible. The need to improve efficiency and the need to reduce power consumption are important factors interfering with quantitative and qualitative growth of organic light emitting devices, and consequently it is desirable that these issues be resolved.

### SUMMARY OF THE INVENTION

Aspects of the present invention provide an organic light emitting device that has reduced power consumption due to a voltage reduction by introducing novel hole injection material and novel electron transporting material, and which has improved driving voltage, light emitting efficiency and lifetime.

According to an embodiment of the present invention, there is provided an organic light emitting device comprising: a first electrode; a second electrode; an emissive layer disposed between the first electrode and the second electrode; a first hole injection layer disposed between the first electrode and the emissive layer; and a first electron transport layer disposed between the emissive layer and the second electrode, wherein the hole injection layer comprises a first hole injecting material and a first compound comprising an element selected from the group consisting of Mo, Li, Na, K, Rb, Cs, Be, Mg, Ca, Sr, Ba, and B and an element selected from the group consisting of O, F, S, Cl, Se, Br, and I, and the electron transport layer comprises a first electron transporting material and a second compound, wherein the second compound is Li₂O, MoO₃, BaO, or B₂O₃.

According to an aspect of the present invention, the organic light emitting device may further include a second hole injection layer disposed between the first hole injection layer and the emitting layer, wherein the second hole injection layer comprises a second hole injecting material.

According to an aspect of the present invention, the organic light emitting device may include a second electron transport layer disposed between the first electron transport layer and the second electrode and comprising a second electron transporting material.

The organic light emitting device according to aspects of the present invention has excellent electrical properties, and uses a novel hole injecting material that is suitable for use in fluorescent and phosphorescent devices with any kind of colors, such as red, green, blue, white, or the like. In addition, the organic light emitting device according to aspects of the present invention uses a novel electron transporting material, and thus has improved electron injection ability such that a separate electron injection layer is not necessary. Therefore, compared with the case when a conventional electron transporting material is used, the organic light emitting device according to aspects of the present invention using the novel electron transporting material has improved current and power efficiencies, and has improved driving voltage and lifetime by adjusting the balance of charges injected into an emissive layer. Due to such configuration of the organic light emitting device according to aspects of the present invention, charge injection barriers can be reduced, resulting in reduction in power consumption, and the current efficiency can be maximized by adjusting a charge mobility of the novel hole injecting and electron transporting materials.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIGS. 1A through 1D are schematic cross-sectional views illustrating structures of organic light emitting devices according to embodiments of the present invention;

FIG. 2 is an energy band diagram schematically illustrating differences in HOMO and LUMO levels of layers of an organic light emitting device according to another embodiment of the present invention;

FIG. 3 is a graph showing efficiency properties (Im/W) according to luminance of an organic light emitting device according to an embodiment of the present invention and a conventional organic light emitting device; and

FIG. 4 is a graph showing light emitting efficiency (cd/A) according to luminance of an organic light emitting device according to an embodiment of the present invention and a conventional organic light emitting device.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

To realize an organic light emitting device with high efficiency performance, the charge balance in the emissive layer is very important. For maintaining the charge balance, aspects of the present invention provide a hole injection layer comprising a hole injecting material and a first compound comprising an element selected from the group consisting of Mo, Li, Na, K, Rb, Cs, Be, Mg, Ca, Sr, Ba, and B and an element selected from the group consisting of O, F, S, Cl, Se, Br, and I, and an electron transport layer comprising a second compound and an electron transporting material, wherein the second compound is Li₂O, MoO₃, BaO, or B₂O₃.

The first compound is a novel material for forming a hole injection layer, and an organic light emitting device according to an embodiment of the present invention includes a hole injection layer comprising a mixture of the first compound and a hole injecting material.

As non-limiting examples, the first compound may be a molybdenum oxide, a magnesium fluoride, a cesium fluoride, a boron oxide, or the like. The first compound may be prepared using various methods known in the art.

The hole injecting material can be any known organic compound for forming a hole injection layer, as described above, for example, copper phthalocyanine, 1,3,5-tricarbazolylbenzene, 4,4′-biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine (TCTA), 4,4′,4″-tris(3-methylphenylamino)triphenylamine (m-MTDATA), 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′-diamine (TPD), N,N′-di(naphthalene-1-yl)-N,N′-diphenyl benzidine (α-NPD), N,N′-diphenyl-N,N′-bis(1-naphthyl)-(1,1′-biphenyl)-4,4′-diamine (NPB), poly(9,9-dioctylfluorene-co-N-(4-butylphenyl)diphenylamine) (TFB), poly(9,9-dioctylfluorene-co-bis-N,N-phenyl-1,4-phenylenediamine (PFB), or the like.

Preferably, a mixing ratio of the first compound to the hole injecting material may be in the range of 1:1 to 3:1. When the mixing ratio of the first compound to the hole injecting material is less than 1:1, that is, the amount of the first compound is relatively low compared to the amount of the hole injecting material, the driving voltage may decrease, and interface resistance may increase when the organic light emitting device operates. On the other hand, when the mixing ratio of the first compound to the hole injecting material is greater than 3:1, that is, the amount of the first compound is relatively high compared to the amount of the hole injecting material, the driving voltage increases.

In general, a pure organic-based material is used for reducing a hole injection barrier. In this case, the energy gap between electrodes and the organic-based material should be minimized. However, when the first compound according to aspects of the present invention is used on an interface of an electrode, metallic properties of an element selected from the group consisting of Mo, Li, Na, K, Rb, Cs, Be, Mg, Ca, Sr, Ba, and B can be used, and contact resistance at the electrode interface may be decreased, and thus, interface characteristics of electrodes used in a semiconductor device, that is, ohmic contact characteristics, can be obtained.

An organic light emitting device having such structures described above, according to aspects of the present invention, can reduce a hole injection barrier, and also can reduce contact resistance at the interface of an electrode, and thus when the organic light emitting device operates, it can have a longer lifetime.

An organic light emitting device according to an embodiment of the present invention may include a first hole injection layer comprising the first compound and hole injecting material and a second hole injection layer.

The second hole injection layer may be formed of a second hole injecting material that is conventionally used. For example, the second hole injecting material may comprise at least one selected from the group consisting of copper phthalocyanine, 1,3,5-tricarbazolylbenzene, 4,4′-biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine (TCTA), 4,4′,4″-tris(3-methylphenylamino)triphenylamine (m-MTDATA),1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′diamine (TPD), N,N′-di(naphthalene-1-yl)-N,N′-diphenyl benzidine (α-NPD), N,N′-diphenyl-N,N′-bis(1-naphthyl)-(1,1′-biphenyl)-4,4′-diamine (NPB), poly(9,9-dioctylfluorene-co-N-(4-butylphenyl)diphenylamine) (TFB), poly(9,9-dioctylfluorene-co-bis-N,N-phenyl-1,4-phenylenediamine (PFB), and the like.

As described above, when the organic light emitting device according to aspects of the present invention includes a hole injection layer having a two-layered structure, that is, a first hole injection layer and a second hole injection layer, the effects described above are more obviously realized. In this case, the driving voltage is reduced due to a low barrier of the first hole injection layer and a charge transferring rate is increased due to the presence of the second hole injection layer, resulting in a further reduction in the driving voltage.

The thickness ratio of the first hole injection layer to the second hole injection layer may be in the range of 1:99 to 1:9. When the thickness ratio of the first hole injection layer to the second hole injection layer is less than 1:99, that is, when the thickness of the first hole injection layer is relatively much thinner with respect to the second hole injection layer, interface resistance increases when the organic light emitting device operates. On the other hand, when the thickness ratio of the first hole injection layer to the second hole injection layer is greater than 1:9, that is, when the thickness of the first hole injection layer is not relatively much thinner with respect to the second hole injection layer, the driving voltage increases.

In an organic light emitting device according to aspects of the present invention, an electron injection layer may be omitted without lowering the ability of the electron injection in OLEDs.

In addition, the organic light emitting device may further include another electron transport layer comprising an electron transporting material having an electron mobility of 10⁻⁸ cm/V or more in an electric field of 800 to 1000 (V/cm)^{1/2} in addition to the electron transport layer described above. In more detail, the organic light emitting device according to aspects of the present invention includes a first electron transport layer comprising a first electron transporting material and a second compound that is one selected from Li₂O, MoO₃, BaO, and B₂O₃, and a second electron transport layer comprising a second electron transporting material. When the organic light emitting device includes a two-layered electron transport layer as described above, much more systematic electron injection is possible compared with the case where the organic light emitting device includes only a single-layered electron transport layer. Thus, power consumption is significantly reduced due to driving voltage reduction.

As described above, the second electron transporting material has an electron mobility of 10⁻⁸ cm/V or more, preferably 10⁻⁴ to 10⁻⁸ cm/V, in an electric field of 800 to 1000 (V/cm)^{1/2}, and can be ZnQ2, Bebq2, or the like.

The first electron transporting material may comprise an electron transporting material having an electron mobility of 10⁻⁸ cm/V or more, as with the second electron transporting material, and may be the same as or different from the second electron transporting material. For example, the first electron transporting material may have an electron mobility different from that of the second electron transporting material in terms of charge transferring properties.

The thickness ratio of the first electron transport layer to the second electron transport layer may be in the range of 1:1 to 1:2.

As a non-limiting example, both the first and the second electron transporting materials may be Bebq2, and the second compound may be Li₂O.

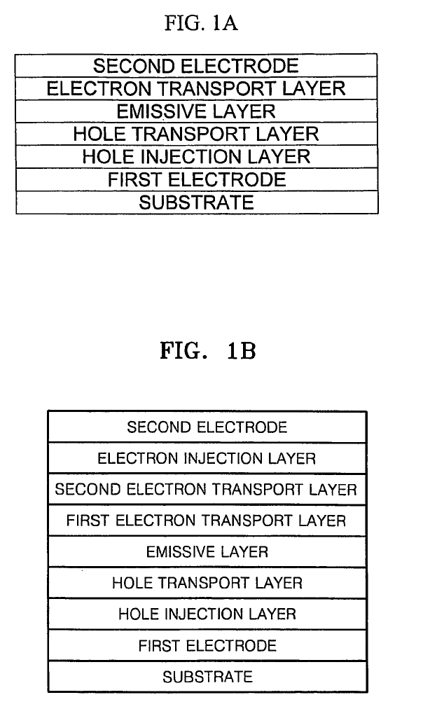

In the organic light emitting device including the two-layered electron transport layer (refer to FIGS. 1B and 1C), the first electron transport layer controls the charge transferring rate, and the second electron transport layer reduces the electron injection barrier.

The first electron transport layer comprises a first electron transporting material and a second compound that is an electron transporting material and has dipole properties. The first electron transporting material may be LiF, BaF, CsF, NaF, or the like, and the second compound may be LiF.

The first electron transporting material of the first electron transport layer may be Bebq2.

The organic light emitting device of the present invention may not require the electron injection layer as described above.

The organic light emitting device according to aspects of the present invention may have various structures. FIGS. 1A through 1D are schematic cross-sectional views illustrating structures of organic light emitting devices according to embodiments of the present invention.

The organic light emitting device may have a structure of an anode, a hole injection layer (HIL), a hole transport layer (HTL), an emissive layer (EML), an electron transport layer (ETL), an electron injection layer (EIL), and a cathode, as illustrated in FIGS. 1A through 1C. As non-limiting examples, the organic light emitting device may have one of the following structures: having one of the following structures:

first electrode/ hole injection layer/hole transport layer/emissive layer/electron transport layer/second electrode (FIG. 1A);

first electrode/hole injection layer/hole transport layer/emissive layer/first electron transport layer/second electron transport layer/electron injection layer/second electrode (FIG. 1B);

first electrode/injection layer/hole transport layer/emissive layer/hole blocking layer/first electron transport layer/second electron transport layer/electron injection layer/second electrode (FIG. 1C); or

first electrode/first hole injection layer/second hole injection layer/hole transport layer/emissive layer/electron transport layer/second electrode (FIG. 1D).

In addition, the organic light emitting device may further include additional layers, such as one-layered or two-layered intermediate layers, if desired.

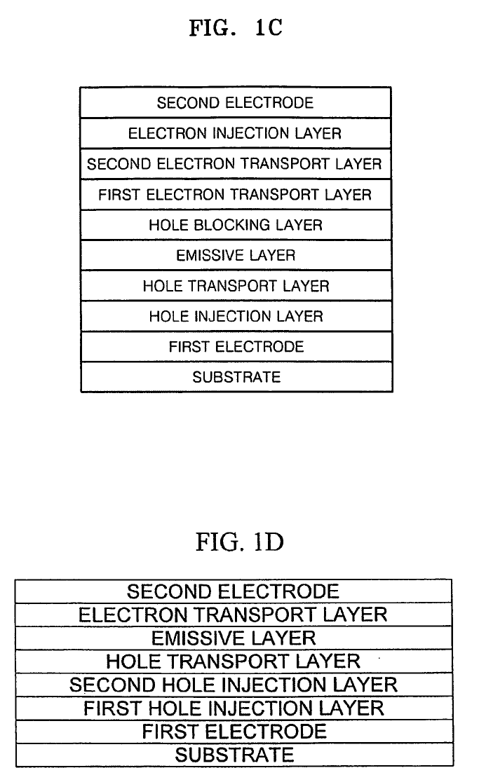

FIG. 2A illustrates an energy band diagram schematically showing a difference between HOMO and LUMO levels (that is, the energy level of the highest occupied molecular orbital (HOMO) and the energy level of the lowest unoccupied molecular orbital (LUMO), respectively) of layers of an organic light emitting device according to the embodiment of FIG. 1A.

Hereinafter, a method of manufacturing an organic light emitting device according to an embodiment of the present invention will be described with reference to the organic light emitting device illustrated in FIG. 1C.

First, a first electrode formed of a material having a high work function is formed on a substrate.. The first electrode may be formed by deposition or sputtering. The first electrode may be an anode. Herein, the substrate may be any substrate used in conventional organic light emitting devices such as, for example, a glass substrate or a plastic substrate having good mechanical strength, thermal stability, transparency, surface smoothness, manageability and waterproofness. Specifically, the material for the anode can be a transparent and highly conductive material, such as ITO, IZO, SnO₂, ZnO, or the like.

Next, a hole injection layer (HIL) may be formed on the first electrode using a method such as vacuum deposition, spin coating, casting, Langmuir Blodgett (LB) deposition, or the like. For example, the first compound and hole injecting material as the material for forming an HIL can be co-deposited.

When the HIL is formed by vacuum deposition, vacuum deposition conditions may vary according to the compound used to form the HIL, and the desired structure and thermal properties of the HIL to be formed. In general, however, the vacuum deposition may be performed at a deposition temperature of 50-500° C., a pressure of 10⁻⁸-10⁻³ torr, and a deposition speed of 0.01-100 Å/sec. The thickness of the HIL may be in the range of 10 Å to 5 μm.

A hole transport layer (HTL) may be formed on the HIL using a method such as vacuum deposition, spin coating, casting, LB deposition, or the like. When the HTL is formed by vacuum deposition or spin coating, the deposition and coating conditions may vary according to the compounds used to form the HTL. In general, however, the deposition and coating conditions are similar to those used for the formation of the HIL.

A material for forming the HTL may be a material conventionally used to form a HTL, such as, for example, a carbazole derivative such as N-phenylcarbazole, polyvinylcarbazole, or the like, a conventional amine derivative having an aromatic condensation ring, such as N,N′-bis(3-methylphenyl)-N,N′-diphenyl-[1,1-biphenyl]-4,4′-diamine (TPD), N,N′-di(naphthalene-1-yl)-N,N′-diphenyl benzidine (α-NPD), or the like.

Next, an emissive layer (EML) may be formed on the HTL. The material for forming the EML is not particularly limited. The EML may be formed using a method such as vacuum deposition, spin coating, casting, LB deposition, or the like.

A material for forming a blue emissive layer may be oxadiazole dimer dyes (Bis-DAPOXP)), spiro compounds (Spiro-DPVBi, Spiro-6P), triarylamine compounds, bis(styryl)amine (DPVBi, DSA), 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BCzVB), 4,4-bis[4-(di-p-tolylamino)styryl]biphenyl (DPAVBi), 4-(di-p-tolylamino)-4′-[(di-p-tolylamino)styryl]stilbene (DPAVB), 4,4′-bis[4-(diphenylamino)styryl]biphenyl (BDAVBi), bis(3,5-difluoro-2-(2-pyridyl)phenyl-(2-carboxypyridyl)iridium III (FIrPic), or the like. A material for forming a green emissive layer may be 3-(2-benzothiazolyl)-7-(diethylamino)coumarin (Coumarin 6) 2,3,6,7-tetrahydro-1,1,7,7,-tetramethyl-1H,5H,11H-10-(2-benzothiazolyl)quinolizino-[9,9a,1gh]coumarin (C545T), N,N′-dimethyl-quinacridone (DMQA), tris(2-phenylpyridine)iridium (III) (Ir(ppy)3), or the like. A material for forming a red emissive layer may be tetraphenylnaphthacene (Rubrene), tris(1-phenylisoquinoline)iridium (III) (Ir(piq)3), bis(2-benzo[b]thiophene-2-yl-pyridine) (acetylacetonate)iridium (III) (Ir(btp)2(acac)), tris(dibenzoylmethane)phenanthroline europium (III) (Eu(dbm)3(phen)), tris[4,4′-di-tert-butyl-(2,2′)-bipyridine]ruthenium (III) complex (Ru(dtb-bpy)3*2(PF6)), DCM1, DCM2, Eu(thenoyltrifluoroacetone)3 (Eu(TTA)3, butyl-6-(1,1,7,7-tetramethyljulolidyl-9-enyl)-4H-pyran (DCJTB), or the like. In addition, the material for forming the EML may include as a polymer emitting material an aromatic compound comprising nitrogen and polymers such as phenylenes, phenylene vinylenes, thiophenes, fluorenes, spiro-fluorenes, or the like; however, the present invention is not limited thereto.

The thickness of the EML may be in the range of 10 to 500 nm, or more specifically, in the range of 50 to 120 nm. As a specific, non-limiting example, the thickness of the EML when formed of a blue emitting material may be 70 nm. When the thickness of the EML is less than 10 nm, the leakage current increases so that the efficiency and lifetime of the organic light emitting device decreases. On the other hand, when the thickness of the EML is greater than 500 nm, driving voltage is increased.

If desired, the EML can be prepared by adding an emissive dopant to a host material for the EML. As non-limiting examples, the fluorescent host material may be tris(8-hydroxy-quinolinato)aluminum (Alq3), 9,10-di(naphth-2-yl)anthracene (AND), 3-tert-butyl-9,10-di(naphth-2-yl)anthracene (TBADN), 4,4′-bis(2,2-diphenyl-ethene-1-yl)-4,4′-biphenyl (DPVBi), 4,4′-bis(2,2-diphenyl-ethene-1-yl)-4,4′-dimethylphenyl (p-DMDPVBi), tert(9,9-diarylfluorene)s (TDAF), 2-(9,9′-spirobifluorene-2-yl)-9,9′-spirobifluorene (BSDF), 2,7-bis(9,9′-spirobifluorene-2-yl)-9,9′-spirobifluorene (TSDF), bis(9,9-diarylfluorene)s (BDAF), 4,4′-bis(2,2-diphenyl-ethene-1-yl)-4,4′-di-(tert-butyl)phenyl (p-TDPVBi), or the like. A phosphorescence host material may be 1,3-bis(carbazol-9-yl)benzene (mCP), 1,3,5-tris(carbazol-9-yl)benzene (tCP), 4,4′,4″-tris(carbazol-9-yl)triphenylamine (TcTa), 4,4′-bis(carbazol-9-yl)biphenyl (CBP), 4,4′-bis(9-carbazolyl)-2,2′-dimethyl-biphenyl (CBDP), 4,4′-bis(carbazol-9-yl)-9,9-dimethyl-fluorene (DMFL-CBP), 4,4′-bis(carbazol-9-yl)-9,9-bis(9-phenyl-9H-carbazol)fluorene (FL-4CBP), 4,4′-bis(carbazol-9-yl)-9,9-di-tolyl-fluorene (DPFL-CBP), 9,9-bis(9-phenyl-9H-carbazol)fluorene (FL-2CBP), or the like.

Herein, the amount of the dopant varies according to the material that forms the EML. In general, the amount of the dopant may be in the range of 3-10 parts by weight based on 100 parts by weight of the total material forming the EML (total weight of host and dopant). If the amount of the dopant is outside this range, light emitting characteristics of the organic light emitting device may be degraded. According to specific, non-limiting example, the dopant may be 4,4′-bis[4-(di-p-tolylamino)styryl]biphenyl (DPAVBi), and the fluorescent host may be 9,10-di(naphth-2-yl)anthracene (ADN) or 3-tert-butyl-9,10-di(naphth-2-yl)anthracene (TBADN).

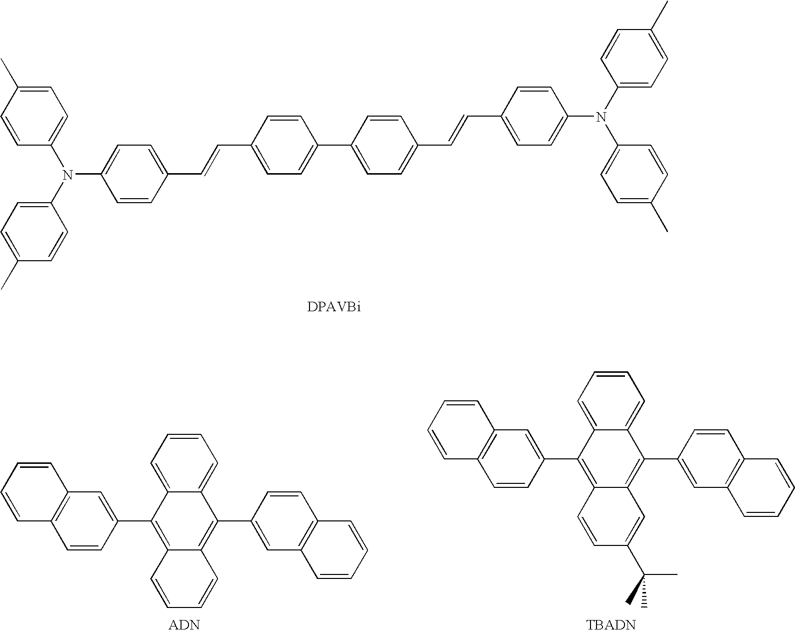

Next, an electron transport layer (ETL) is formed on the EML using the electron transporting material and the second compound described above. The ETL may be formed by vacuum deposition.

The amount of the second compound may be in the range of 30 to 70 parts by weight based on 100 parts by weight of the electron transporting material. When the amount of the second compound is less than 30 parts by weight based on 100 parts by weight of the electron transporting material, the effect of reduction of driving voltage is relatively insignificant. On the other hand, when the amount of the second compound is greater than 70 parts by weight based on 100 parts by weight of the electron transporting material, charge stability may decrease.

The electron transporting material may be an electron transporting material having an electron mobility of 10⁻⁸ cm/V or more, or more specifically, in the range of 10⁻⁵ to 10⁻⁶ cm/V, in an electric field of 800 to 1000 (V/cm)^{1/2}.

If the electron mobility of the electron transport layer is less than 10⁻⁸ cm/V, electron injection to the EML may be excessive, resulting in poor charge balance.

The electron transporting material may be bis(10-hydroxybenzo[h]quinolinato)beryllium (Bebq₂) represented by Formula 2 below.

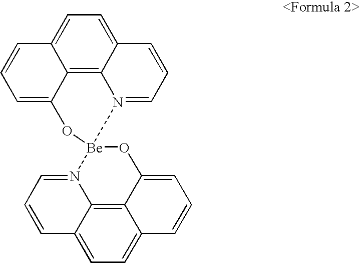

Finally, a second electrode (typically, a cathode) is formed on the EIL by depositing a metal by vacuum deposition, sputtering, or the like. The metal is selected to have a low work function and may be a metal, alloy, an electrically conductive compound, or a mixture thereof. In particular, the metal that forms the cathode may be Li, Mg, Al, Al—Li, Ca, Mg—In, Mg—Ag, or the like. In a top emission organic light emitting device, the cathode may be formed of a transparent material such as ITO or IZO.

A method of manufacturing an organic light emitting device according to another embodiment of the present invention will now be described. In this embodiment, a first electron transport layer is formed on the EML by vacuum deposition using a first electron transporting material and the second compound described above and a second electron transport layer is formed on the first electron transport layer by vacuum deposition using a second electron transporting material, as illustrated in FIG. 1B.

Aspects of the present invention will be described in greater detail with reference to the following examples. The following examples are for illustrative purposes only and are not intended to limit the scope of the invention.

### EXAMPLE 1

### Manufacture of Organic Light Emitting Device

As an anode, a Corning 15 Ω/cm² (1200 Å) ITO glass substrate was cut to a size of 50 mm×50 mm×0.7 mm, and was ultrasonically washed with isopropyl alcohol and pure water for 5 minutes, respectively. The ITO glass substrate was irradiated with ultraviolet rays for 30 minutes and washed with ozone.

Then, molybdenum oxide and NPB were co-deposited on the substrate to form a first hole injection layer with a thickness of 100 Å. Subsequently, F16-TCNQ was coated on the first hole injection layer to form a second hole injection layer.

NPB was vacuum deposited on the second hole injection layer to form a hole transport layer having a thickness of 60 nm. After the formation of the hole transport layer, 100 parts by weight of Alq₃ as a host and 5 parts by weight of C545T as a dopant were vacuum deposited on the hole transport layer to form an emissive layer.

Then, 50 parts by weight of LiF and 50 parts by weight of BeBq₂ were vacuum co-deposited on the emissive layer to form an electron transport layer (ETL) having a thickness of 35 nm.

Al was vacuum deposited on the ETL to form a cathode (that is, an Al electrode) having a thickness of 3000 Å. Thus, the manufacture of an organic light emitting device was completed.

### EXAMPLE 2

### Manufacture of Organic Light Emitting Device

An organic light emitting device was manufactured in the same manner as in Example 1, except that 50 parts by weight of lithium quinolate and 50 parts by weight of BeBq₂ were vacuum co-deposited to form the electron transport layer.

### EXAMPLE 3

### Manufacture of Organic Light Emitting Device

As an anode, a Corning 15 Ω/cm2 (1200 Å) ITO glass substrate was cut to a size of 50 mm×50 mm×0.7 mm, and was ultrasonically washed with isopropyl alcohol and pure water for 5 minutes, respectively. The ITO glass substrate was irradiated with ultraviolet rays for 30 minutes and washed with ozone.

A hole injection layer formed of CuPc was formed on the substrate to a thickness of 10 nm.

NPB was vacuum deposited on the hole injection layer to form a hole transport layer having a thickness of 60 nm. After the formation of the hole transport layer, 100 parts by weight of Alq3 as a host and 5 parts by weight of C545T as a dopant were vacuum deposited on the hole transport layer to form an emissive layer.

Then, Bebq2 was vacuum deposited on the emissive layer to form a first electron transport layer (ETL1) having a thickness of 10 nm.

30 parts by weight of LiF and 70 parts by weight of Bebq2 were vacuum co-deposited on the ETL1 to form a second electron transport layer (ETL2) having a thickness of 25 nm.

Al was vacuum deposited on the ETL2 to form a cathode (that is, an Al electrode) having a thickness of 3000 Å. Thus, the manufacture of an organic light emitting device was completed.

### EXAMPLE 4

### Manufacture of Organic Light Emitting Device

An organic light emitting device was manufactured in the same manner as in Example 1, except that 50 parts by weight of lithium quinolate and 50 parts by weight of Bebq2 were vacuum co-deposited to form the ETL2.

### COMPARATIVE EXAMPLE 1

### Manufacture of Organic Light Emitting Device

An organic light emitting device was manufactured in the same manner as in Example 1, except that Bebq₂ alone was used in the formation of the electron transport layer.

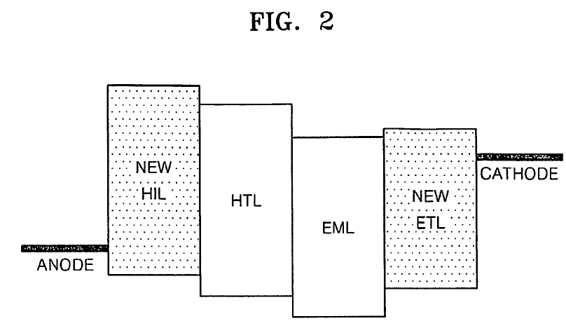

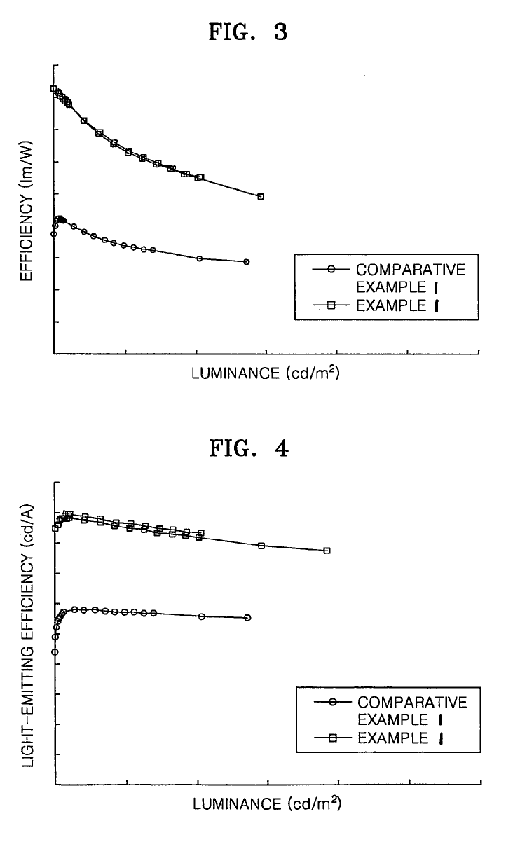

Power efficiency with respect to current density of each of the organic light emitting devices manufactured in Example 1 and Comparative Example 1 was measured. The results are shown in the graphs of FIGS. 3 and 4.

An organic light emitting device according to aspects of the present invention has excellent electrical properties, and uses a novel hole injecting material that is suitable for use in fluorescent and phosphorescent devices with any kind of colors, such as red, green, blue, white, or the like. In addition, the organic light emitting device according to aspects of the present invention uses a novel electron transporting material, and thus has improved electron injection ability in spite of not having an electron injection layer. Therefore, compared with the case where a conventional electron transporting material is used, the organic light emitting device according to aspects of the present invention using the novel electron transporting material has improved current and power efficiencies, and has improved driving voltage and lifetime by adjusting the balance of charges injected into an emissive layer. Due to such configuration of the organic light emitting device according to aspects of the present invention, charge injection barriers can be reduced, resulting in reduction in power consumption, and the current efficiency can be maximized by adjusting a charge mobility of the novel hole injecting and electron transporting materials. In addition, the organic light emitting device can have a higher luminance and a longer lifetime.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An organic light emitting device comprising:
a first electrode;
a second electrode;
an emissive layer disposed between the first electrode and the second electrode;
a first hole injection layer disposed between the first electrode and the emissive layer; and
a first electron transport layer disposed between the emissive layer and the second electrode,
wherein the first hole injection layer comprises a first hole injecting material and a first compound comprising an element selected from the group consisting of Mo, Li, Na, K, Rb, Cs, Be, Mg, Ca, Sr, Ba, and B and an element selected from the group consisting of O, F, S, Cl, Se, Br, and I, and the electron transport layer comprises a first electron transporting material and a second compound, wherein the second compound is Li₂O, MoO₃, BaO, or B₂O₃.

2. The organic light emitting device of claim 1, wherein the first hole injecting material is one selected from the group consisting of copper phthalocyanine, 1,3,5-tricarbazolylbenzene, 4,4′- biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine (TCTA), 4,4′,4″-tris(3-methylphenylamino)triphenylamine (m-MTDATA), 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′-diamine (TPD), N,N′-di(naphthalene-1-yl)-N,N′-diphenyl benzidine (α-NPD), N,N′-diphenyl-N,N′-bis(1-naphthyl)-(1,1′-biphenyl)-4,4′-diamine (NPB), poly(9,9-dioctylfluorene-co-N-(4-butylphenyl)diphenylamine) (TFB), and poly(9,9-dioctylfluorene-co-bis-N,N-phenyl-1,4-phenylenediamine (PFB).

3. The organic light emitting device of claim 1, wherein a mixing ratio of the first compound and the first hole injecting material is in the range of 1:1 to 3:1.

4. The organic light emitting device of claim 1, wherein the first compound is selected from the group consisting of a molybdenum oxide, a magnesium fluoride, a cesium fluoride, and a boron oxide.

5. The organic light emitting device of claim 1, further comprising a second hole injection layer disposed between the first hole injection layer and the emissive layer, the second hole injection layer comprising a second hole injecting material.

6. The organic light emitting device of claim 5, wherein the second hole injecting material is at least one selected from the group consisting of copper phthalocyanine, 1,3,5-tricarbazolylbenzene, 4,4′- biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine (TCTA), 4,4′,4″-tris(3-methylphenylamino)triphenylamine (m-MTDATA), 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′-diamine (TPD), N,N′-di(naphthalene-1-yl)-N,N′-diphenyl benzidine (α-NPD), N,N′-diphenyl-N,N′-bis(1-naphthyl)-(1,1′-biphenyl)-4,4′-diamine (NPB), poly(9,9-dioctylfluorene-co-N-(4-butylphenyl)diphenylamine) (TFB), and poly(9,9-dioctylfluorene-co-bis-N,N-phenyl-1,4-phenylenediamine (PFB).

7. The organic light emitting device of claim 5, wherein a thickness ratio of the first hole injection layer to the second hole injection layer is in the range of 1:99 to 1:9.

8. The organic light emitting device of claim 1, wherein the amount of the second compound is in the range of 30 to 70 parts by weight based on 100 parts by weight of the first electron transporting material.

9. The organic light emitting device of claim 1, wherein the first electron transporting material has an electron mobility of 10⁻⁸ cm/V or more in an electric field of 800 to 1000 (V/cm)^{1/2}.

10. The organic light emitting device of claim 1, wherein the first electron transporting material is bis(10-hydroxybenzo[h]quinolinato)beryllium (Bebq₂) represented by Formula 2 below.

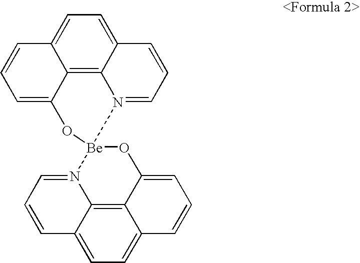

11. The organic light emitting device of claim 1, further comprising a second electron transport layer disposed between the first electron transport layer and the second electrode, the second electron transport layer comprising a second electron transporting material.

12. The organic light emitting device of claim 11, wherein the second electron transporting material has an electron mobility of 10⁻⁸ cm/V or more in an electric field of 800 to 1000 (V/cm)^{1/2}.

13. The organic light emitting device of claim 11, wherein the second electron transporting material has an electron mobility in the range of 10⁻⁴ to 10⁻⁸ cm/V in an electric field of 800 to 1000 (V/cm)^{1/2}.

14. The organic light emitting device of claim 11, wherein a thickness ratio of the first electron transport layer to the second electron transport layer is in the range of 1:1 to 1:2.

15. The organic light emitting device of claim 1, further comprising at least one layer selected from the group consisting of a second hole injection layer, a hole transport layer, an electron blocking layer, an emissive layer, a hole blocking layer, a second electron transport layer, and an electron injection layer.

16. The organic light emitting device of claim 1, having one of the following structures:
first electrode/first hole injection layer/hole transport layer/emissive layer/first electron transport layer/second electrode;
first electrode/first hole injection layer/second hole injection layer/hole transport layer/emissive layer/first electron transport layer/second electrode;
first electrode/first hole injection layer/hole transport layer/emissive layer/first electron transport layer/second electron transport layer/electron injection layer/second electrode; or
first electrode/first hole injection layer/hole transport layer/emissive layer/hole blocking layer/first electron transport layer/second electron transport layer/electron injection layer/second electrode.
